(19) United States
(12) Patent Application Publication
(10) Pub. No.: US 2012/0325296 A1
(43) Pub. Date: Dec. 27, 2012

(54) GRAPHENE-ON-SUBSTRATE AND TRANSPARENT ELECTRODE AND TRANSISTOR INCLUDING THE GRAPHENE-ON-SUBSTRATE

(75) Inventors: Yun-sung WOO, Yongin-si (KR); Jae-young CHOI, Suwon-si (KR); Hyeon-jin SHIN, Suwon-si (KR); Seon-mi YOON, Yongin-si (KR)

(73) Assignee: SAMSUNG ELECTRONICS CO., LTD., Suwon-si (KR)

(21) Appl. No.: 13/530,567

(22) Filed: Jun. 22, 2012

(30) Foreign Application Priority Data
Jun. 24, 2011 (KR) 10-2011-0061793

(51) Int. Cl. H01L 29/06; H01L 31/06; H01L 29/78; B82Y 99/00

(52) U.S. Cl. 136/252; 257/9; 257/29; 257/E29.255; 257/E29.005; 977/762

(57) ABSTRACT

A graphene-on-substrate includes a substrate, a first intermediate layer disposed on the substrate, and graphene disposed on the first intermediate layer, where the first intermediate layer comprises a material having an intermediate polarity value between a polarity of the substrate and a polarity of the graphene.

### CROSS-REFERENCE TO RELATED APPLICATIONS

This application claims priority to Korean Patent Application No. 10-2011-0061793, filed on Jun. 24, 2011, and all the benefits accruing therefrom under 35 U.S.C. §119, the content of which in its entirety is herein incorporated by reference.

### BACKGROUND

1. Field

The present disclosure relates to a graphene-on-substrate, and a transparent electrode including the graphene-on-substrate and a transistor including the graphene-on-substrate, and more particularly, to a graphene-on-substrate with enhanced graphene-to-substrate adhesion due to a material having a predetermined polarity value between the polarity of the graphene and the polarity of the substrate, and a transparent electrode and a transistor including the graphene-on-substrate.

2. Description of the Related Art

Graphene generally means a layered structure of two-dimensional (“2D”) planar sheets of carbon atoms arranged in a hexagonal lattice structure. Such graphene is chemically substantially stable and has electrically semi-metallic characteristics because a conduction band and a valence band thereof meet together at Dirac points.

According to Ballistic electron transport in graphene with zero electron effective mass, high mobility transistors may be manufactured from graphene. A current of about 108 amperes per square centimeters (A/cm²) may be applied to graphene, which is about 100 times as high as the maximum current density of copper. A single layer of graphene is optically transparent and may have a transparency of about 97.4%. Therefore, using the physical and optical characteristics, graphene may be used in transparent electrodes or interconnects of display devices or solar cells and in high-performance transistors, and there is ongoing research into the development of such devices using graphene.

To use graphene in transparent electrodes, interconnects, transistors or the like, methods of depositing the graphene on a metal layer and transferring the graphene to a substrate may be used. Binding characteristics of the graphene thin film to the substrate may vary depending on a hydrophobic/hydrophilic characteristics of the substrate such that graphene, which is hydrophobic, may not substantially be bound to a hydrophilic oxide layer substrate.

### SUMMARY

Provided is a graphene-on-substrate with enhanced graphene-to-substrate adhesion.

Provided is a transparent electrode employing the graphene-on-substrate.

Provided is a transistor employing the graphene-on-substrate.

Additional aspects will be set forth in part in the description which follows and, in part, will be apparent from the description, or may be learned by practice of the presented embodiments.

According to an embodiment of the invention, a graphene-on-substrate includes: a substrate; a first intermediate layer disposed on the substrate; and graphene disposed on the first intermediate layer, where the first intermediate layer includes a material having a polarity value between a polarity of the substrate and a polarity of the graphene.

In an embodiment, the graphene-on-substrate may further include a second intermediate layer disposed on the graphene.

In some embodiments, each of the first and second intermediate layers may have a contact angle with water in a range of from about 25° to about 95°.

In some embodiments, each of the first and second intermediate layers may include at least one selected from among boron nitride, graphene oxide and a polymer-based material.

In some embodiments, each of the first and second intermediate layers may be in a film form.

In some embodiments, each of the first and second intermediate layers may be a film including a plurality of flakes.

According to another embodiment of the invention, a transparent electrode includes the above-described graphene-on-substrate.

According to another embodiment of the invention, a transistor includes the above-described graphene-on-substrate.

### BRIEF DESCRIPTION OF THE DRAWINGS

These and/or other features will become apparent and more readily appreciated from the following description of the embodiments, taken in conjunction with the accompanying drawings of which:

FIGS. 1 to 6 are schematic cross-sectional views of embodiments of graphene-on-substrate according to the present disclosure;

FIGS. 7 and 8 are schematic cross-sectional views of embodiments of a transistor including a graphene base according to the present disclosure; and

FIG. 9 is a schematic cross-sectional view of an embodiment of a dye-sensitized solar cell dye including a graphene base according to the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

According to embodiments of the present disclosure, a graphene-on-substrate may have enhanced graphene-to-substrate adhesion with an intermediate layer having a polarity value between the polarity of graphene and the polarity of the substrate.

In an embodiment of manufacturing a device such as a transparent electrode or a transistor using graphene, after the graphene is transferred to a predetermined substrate, a patterning process may be performed thereon. When a binding force between the graphene and the substrate is substantially low, the graphene may be separated from the substrate during the patterning process. In an embodiment, graphene may directly contact a substrate, which may be formed of plastic, glass, oxide, or the like. A substrate formed of the above-mentioned material may form a hydrogen bond with water via O—H bonds on a surface of the substrate such that the substrate may have highly wettability and hydrophilic characteristics. Graphene has hydrophobic characteristics since graphene is non-polar as it consists of polycyclic aromatic hydrocarbons with carbon atoms sp²-bonded in a hexagonal ring. Graphene may have a contact angle of 127.0° with surface water.

Accordingly, the graphene-to-substrate binding force may be substantially weak for a patterning process, and thus the graphene may be separated from the substrate during the patterning process.

In an embodiment, a graphene-on-substrate includes an intermediate layer having an intermediate polarity value in a range between the polarity value of the hydrophobic graphene and the polarity value of the hydrophilic substrate such that the graphene-to-substrate binding force substantially increases.

The polarity of the intermediate layer may have an intermediate value between the polarity of the hydrophobic graphene and the polarity of the hydrophilic substrate. In an embodiment, the intermediate polarity value of the intermediate layer may be from about 20% to about 80% of an entire polarity range between the polarity of the graphene and the polarity of the substrate. In some embodiments, the intermediate polarity value of the intermediate layer may be from about 30% to about 70% of the entire polarity range between the polarity of the graphene and the polarity of the substrate. Assuming that a relative hydrophilicity of the graphene is “0” and a relative hydrophilicity of the substrate is “100”, the intermediate layer may have a polarity value greater than or equal to about 20% of the hydrophilicity of the graphene and less than or equal to about 80% of the hydrophilicity of the substrate.

The hydrophilic degree of the intermediate layer may be defined by a contact angle with water. In some embodiments, the intermediate layer may have a contact angle with water in a range from about 25° to about 95°. In an embodiment, the graphene-on-substrate may have an intermediate polarity value between the polarity of the graphene and the polarity of the substrate within a contact angle range of about 25° to about 95°.

The intermediate layer may include a material having such an intermediate polarity value between the polarity value of graphene and the polarity value of the substrate. In an embodiment, for example, the intermediate layer may include at least one of boron nitride, graphene oxide and a polymer-based material. In such an embodiment, boron nitride having a contact angle of about 67.4° with water on its surface or graphene oxide having a contact angle of about 73° with water on its surface has a hydrophilicity less than the hydrophilicity of graphene.

In some embodiments, the intermediate layer may include boron nitride thin film may. In an embodiment, the intermediate layer may include crystalline boron nitrides, for example, hexagonal boron nitride (“h-BN”) or cubic boron nitride (“c-BN”), but not being limited thereto.

In an embodiment, the polymer-based material includes polyvinyl alcohols, polyvinyl acetates, epoxies, polycarbonates and polystyrenes, for example, but not being limited thereto.

In an embodiment, the intermediate layer may have a film shape having a thickness in a range of about 0.6 nanometer (nm) to about 10 nanometers (nm). In an embodiment, the intermediate layer film may have a planar shape. In an embodiment, the intermediate layer film may have a single-layer structure or a multi-layer structure. In an alternative embodiment, the intermediate layer film may be a film including a plurality of uniformly distributed flakes.

In an embodiment, where the intermediate layer has a film shape having a planar single-layer structure or a multi-layer structure, the intermediate layer may be formed by simple stacking on a substrate. In an embodiment, where an intermediate layer film is a plurality of uniformly distributed flakes, after a uniform dispersion of, for example, graphene flakes in a solvent by, for example, ultrasonication, the dispersion may be coated on a substrate by, for example, spraying, to form a film of flakes, which may be used as the intermediate layer. In such an embodiment, the solvent may be N-methyl-2-pyrrolidone (“NMP”), dichlorobenzene, chloroform, dimethylformamide (“DMF”), N,N′-dimethylacetamide (“DMAC”) or diethyleneglycol (“DEG”), for example, but not being limited thereto.

In an embodiment, the substrate for stacking the intermediate layer includes at least one of a metal oxide substrate, a silica-based substrate and a plastic substrate, for example, but not being limited thereto. In an embodiment, the metal oxide substrate may include at least one of a SiO₂ substrate, a ZrO₂ substrate, a TiO₂ substrate, a sapphire substrate, a HfO₂ substrate and an Al₂O₃ substrate, but not being limited thereto. In an embodiment, the silica-based substrate may include a SiO₂ substrate, a glass substrate, and a quartz substrate, for example, but not being limited thereto. In an embodiment, the plastic substrate include at least one of polyethylene naphthalene (“PEN”), polyethylene terephthalate (“PET”) and polyether sulfone (“PES”), for example, but not being limited thereto.

In an embodiment, the intermediate layer may be disposed between the graphene and the substrate. In an embodiment, an additional intermediate layer may be disposed on the graphene. In such an embodiment, where an additional intermediate layer is disposed on the graphene, the graphene-on-substrate may have a binding force greater than a binding force when an additional material, for example, a dielectric material, is disposed on the graphene.

In some embodiments, the substrate may have a thickness in a range of about 1 micrometer (μm) to about 1 centimeter (cm). The size of the substrate may be determined based on the device, to which the substrate is to be applied.

As used herein, the “graphene” stacked on the intermediate layer refers to a polycyclic aromatic molecule including a plurality of carbon atoms linked to each other by a covalent bond. The plurality of carbon atoms may form a six-membered ring as a standard repeating unit, or may further include 5-membered rings and/or 7-membered rings. Accordingly, the graphene may be a single layer of covalently bonded carbon atoms having generally sp² hybridization. The graphene may have any of various structures, which may depend upon the content of 5-membered rings and/or 7-membered rings in the graphene. A plurality of graphene layers is often referred to in the art as graphite. However, “graphene,” as used herein, may include one or more layers of single-layered graphene. Thus, as used herein, graphene may refer to a single layer of carbon, or also may refer to a plurality of stacked single layers of graphene.

The graphene may be prepared using any of a variety of methods without limitation. In one embodiment, for example, graphene grown on a metal substrate by chemical vapor deposition (“CVD”) may be used. In another embodiment, a graphene film including a plurality of flakes may be used. In such an embodiment, after uniformly dispersing the graphene flakes in a solvent, the resulting dispersion may be coated on a substrate by centrifugation or spraying to form a graphene film, which may then be stacked on the intermediate layer. In an embodiment, the solvent include at least one of N-methyl-2-pyrrolidone (“NMP”), dichlorobenzene, chloroform, dimethylformamide (“DMF”), N,N′-dimethylacetamide (“DMAC”) and diethyleneglycol (“DEG”), for example, but not being limited thereto.

In some embodiments, the graphene may have a single-layer structure or a multi-layer structure. In an embodiment, graphene in the multi-layer structure may include 2 to 50 layers. In an alternative embodiment, graphene may include 2 to 30 layers. In another alternative embodiment, graphene may include 2 to 20 layers.

In an embodiment, the size of the graphene is not limited to a specific size, and the size of the graphene may be determined based on the characteristics of the device to which the graphene is to be applied.

As described above, by disposing an intermediate layer between hydrophobic graphene and the hydrophilic substrate, the intermediate layer having an intermediate polarity value between the polarity of the graphene and the polarity the substrate, the binding force between the graphene and the substrate may be enhanced. In such an embodiment, separation of the graphene from the substrate during a patterning process may be substantially reduced or effectively prevented, thereby improving the quality of a final device.

As described above, a graphene-on-substrate with an intermediate layer between graphene and a base substrate may have various applications, for example, as a transparent electrode of display devices or solar cells, a field effect transistor (“FET”), or the like.

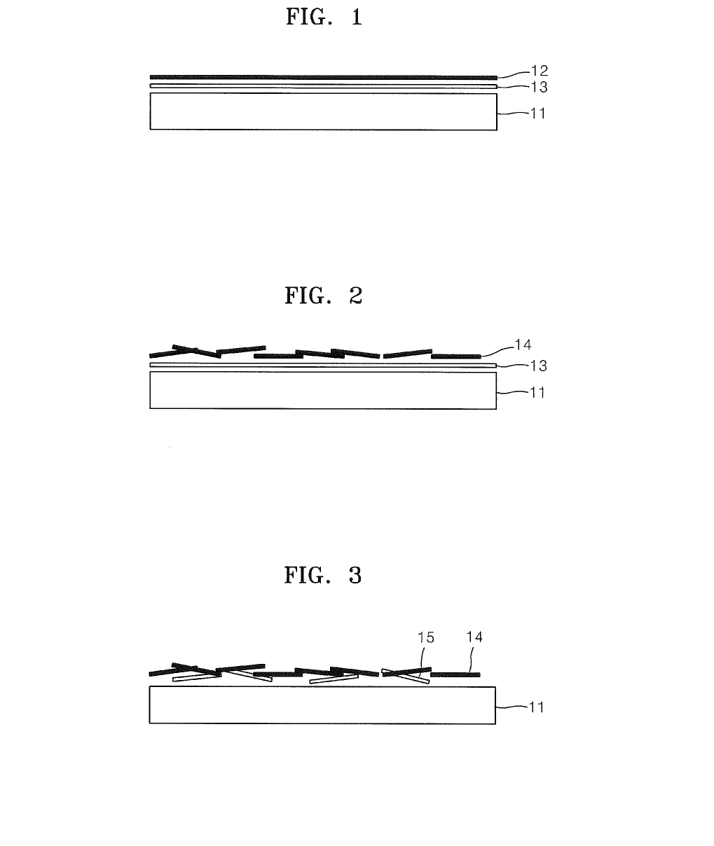

FIG. 1 is a schematic cross-sectional view of an embodiment of a graphene-on-substrate according to the present disclosure. Referring to FIG. 1, the graphene-on-substrate may include an intermediate layer 13 disposed between a substrate 11 and graphene 12. Each of the intermediate layer 13 and the graphene 12 may have a single-layer structure or a multi-layer structure.

FIG. 2 is a schematic cross-sectional view of an alternative embodiment of a graphene-on-substrate according to the present disclosure. Referring to FIG. 2, the graphene-on-substrate may include an intermediate layer 13 disposed between a substrate 11 and graphene 14. The graphene 14 may be a film including a plurality of flakes.

FIG. 3 is a schematic cross-sectional view of another alternative embodiment of a graphene-on-substrate according to the present disclosure. Referring to FIG. 3, the graphene-on-substrate may include an intermediate layer 15 disposed between a substrate 11 and graphene 14. The graphene 14 and the intermediate layer 15 may be formed as a film including a plurality of flakes.

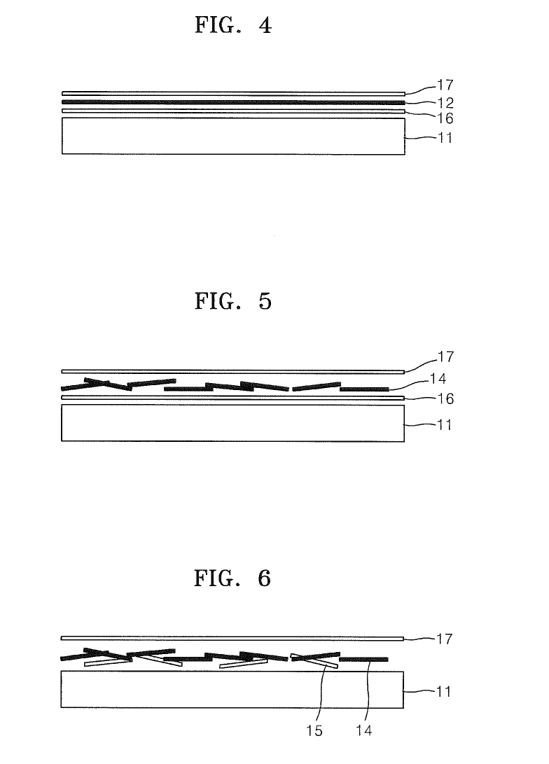

FIG. 4 is a schematic cross-sectional view of another alternative embodiment of a graphene-on-substrate according to the present disclosure. In an embodiment, as shown in FIG. 4, the graphene-on-substrate includes a first intermediate layer 16 between graphene 12 and a substrate 11, and a second intermediate layer 17 further disposed on the graphene 12.

FIG. 5 is a schematic cross-sectional view of another alternative embodiment of a graphene-on-substrate according to the present disclosure. In an embodiment, as shown in FIG. 4, the graphene-on-substrate has the same layer arrangement as the layer arrangement of the graphene-on-substrate of FIG. 4, except that graphene 14 is a film including a plurality of flakes.

FIG. 6 is a schematic cross-sectional view of another alternative embodiment a graphene-on-substrate according to the present disclosure. In an embodiment, as shown in FIG. 4, the graphene-on-substrate has the same layer arrangement as the layer arrangement of the graphene-on-substrate of FIG. 4, except that each of graphene 14 and a first intermediate layer 15 is a film including flakes.

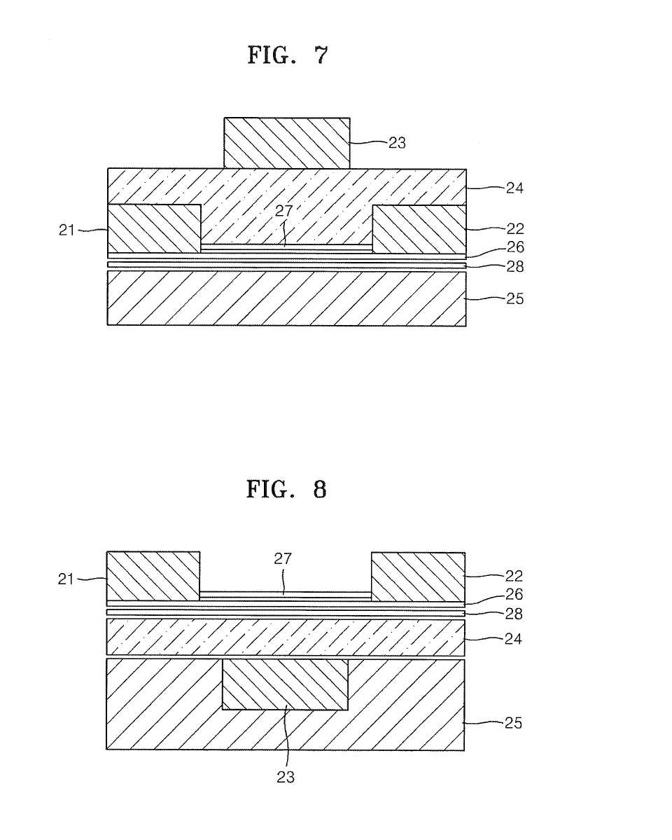

FIGS. 7 and 8 are schematic cross-sectional views of embodiments of FET according to the present disclosure. Referring to FIG. 7, an embodiment of the FET may include a source electrode 21 and a drain electrode 22 on a substrate 25, and a gate electrode 23 on a dielectric 24. In the FET, graphene 26 may serve as a channel, and a first intermediate layer 28 and a second intermediate layer 27 may be disposed opposite sides of the graphene 26 such that binding of the graphene 26 to the dielectric 24 and to the substrate 25, respectively, is substantially improved.

In an alternative embodiment, as shown in FIG. 8, the FET may include a first intermediate layer 28 and a second intermediate layer 27 may be disposed opposite sides of the graphene 26 such that binding of graphene 26 to the dielectric 24 is substantially improved.

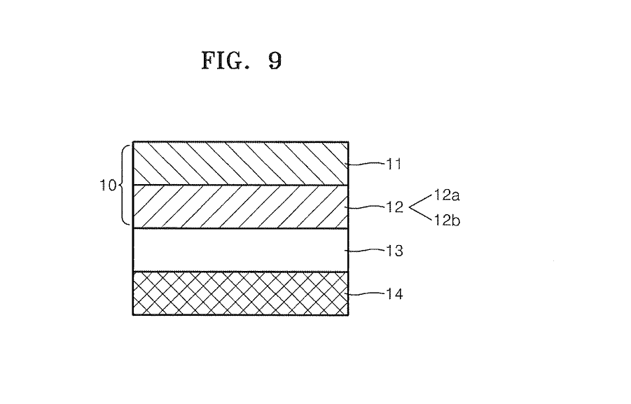

FIG. 9 is a schematic cross-sectional view of an embodiment of a dye-sensitized solar cell including a graphene base and an intermediate layer. In an embodiment, the dye-sensitized solar cell includes a semiconductor electrode 10, an electrolyte layer 13 and an opposing electrode 14. In an embodiment, the semiconductor electrode 10, which includes a conductive transparent substrate 11 and a light absorbing layer 12, may be prepared by coating a colloid solution of a nanoparticulate oxide 12a on a conductive glass substrate, heating the resultant in a high temperature furnace, and adsorbing a dye 12b thereon.

In an embodiment, the conductive transparent substrate 11 may be a transparent electrode. The transparent electrode may be a graphene-on-substrate including the intermediate layer disposed between a transparent substrate and graphene. In an embodiment, the transparent substrate may include transparent polymers such as polyethylene terephthalate, polycarbonate, polyimide and polyethylene naphthalate, or a glass substrate, for example. In such an embodiment, the transparent electrode may also be used as the opposing electrode 14.

In an embodiment of the dye-sensitized solar cell in a bendable configuration, for example, in a cylindrical structure, the opposing electrode 14 includes a flexible material.

The nanoparticulate oxide 12a used in the solar cell may be a semiconductor particle. In some embodiments, the nanoparticulate oxide 12a may be an n-type semiconductor, which provides an anode current as a result of conduction band electrons serving as carriers when excited by light. In an embodiment, the nanoparticulate oxide 12a includes at least one of TiO₂, SnO₂, ZnO₂, WO₃, Nb₂O₅, Al₂O₃, MgO and TiSrO₃, for example. In another embodiment, the nanoparticulate oxide 12a may be anatase-type TiO₂. However, the nanoparticulate oxide 12a is not limited to these metal oxides, which may be used alone or in a combination of at least two thereof. Such semiconductor particles may have a large surface area such that the dye adsorbed on the surface of the semiconductor particles absorbs a large amount of light. In an embodiment, the semiconductor particles may have an average particle diameter of about 20 nm or less.

Any dye that is commonly used in solar cells or photoelectric cells may be used as the dye 12b without limitation. In an embodiment, a ruthenium complex may be used. In an embodiment, the ruthenium complex are RuL₂(SCN)₂, RuL₂(H₂O)₂, RuL₃ and RuL₂, where L is 2,2′-bipyridyl-4,4′-dicarboxylate, or the like. Any dye that has a charge separating capability and sensitization may be used as the dye 12b without limitation. In an embodiment, for example, the dye 12b may be a xanthine dye such as rhodamine B, rose bengal, eosin and erythrosin, a cyanine dye such as quinocyanine and kryptocyanine, a basic dye such as phenosafranine, tyocyn and methylene blue, a porphyrin-based compound such as chlorophyll, Zn porphyrin and Mg porphyrin, an azo dye, a complex such as phthalocyanine and Ru trisbipyridyl, an anthraquinone-based dye and a polycyclic quinone-based dye. In an embodiment, an anthraquinone-based dye and a polycyclic quinone-based dye that are part of a ruthenium complex may also be used. In an embodiment, the aforementioned dyes may be used alone or in a combination of at least two thereof.

In an embodiment, the thickness of the light absorbing layer 12 including the nanoparticulate oxide 12a and the dye 12b may be about 15 μm. In another embodiment, the thickness of the light absorbing layer 12 may be in a range from about 1 μm to about 15 μm. In an embodiment, the light absorbing layer 12 has high series resistance due to its structure and the increased series resistance causes reduction in conversion efficiency, the thickness of the light absorbing layer 12 is thereby controlled to less than about 15 μm to maintain its function and to maintain the series resistance at a low level and effectively prevent reduction in conversion efficiency.

The electrolyte layer 13 used in the dye-sensitized solar cell may be a liquid electrolyte, an ionic liquid electrolyte, an ionic gel electrolyte, a polymer electrolyte and a complex thereof, for example. The electrolyte layer 13 is mainly formed of an electrolyte and includes the light absorbing layer 12. The electrolyte is infiltrated into the light absorbing layer 12 to form the electrolyte layer 13. An iodide-acetonitrile solution may be used as the electrolyte, but any material that has hole transporting or conduction capability may be used without limitation.

In an embodiment, the dye-sensitized solar cell may further include a catalyst layer (not shown). The catalyst layer facilitates oxidation and reduction reaction of the dye-sensitized solar cell. Platinum, carbon, graphite, carbon nanotubes, carbon black, p-type semiconductors and a complex thereof may be used as the catalyst. The catalyst layer is interposed between the electrolyte layer and the opposing electrode. The surface area of the catalyst may be increased using a microstructure. In some embodiments, platinum black may be employed for platinum catalysts and porous carbon may be employed for carbon catalysts. The platinum black may be prepared by anodizing platinum, treating platinum with chloroplatinic acid, or the like. The porous carbon may be prepared by sintering carbon particles, calcinating an organic polymer, or the like.

In an embodiment, the dye-sensitized solar cell may have high conductivity, and high luminance efficiency and processability by employing a flexible transparent electrode including a graphene sheet.

In an embodiment, display devices using the above-described graphene-on-substrate as a transparent electrode, the graphene-on-substrate including an intermediate layer between a substrate and graphene, may be an electronic paper display device, an organic light emitting device, and a liquid crystal display (“LCD”) device, for example. The organic light emitting device is an active light emitting display device that emits light by recombination of electrons and holes in a thin layer made of a fluorescent or phosphorescent organic compound when a current is applied to the thin layer. In an embodiment, organic light emitting device has a structure that includes an anode, a hole transport layer (“HTL”), an emission layer, an electron transport layer (“ETL”) and a cathode that are sequentially disposed on a substrate. In an embodiment, the organic light emitting device may further include an electron injection layer (“EIL”) and a hole injection layer (“HIL”) such that the injection of electrons and holes is facilitated. In an embodiment, the organic light emitting device may further include a hole blocking layer (“HBL”) and a buffer layer, and the like. In such an embodiment, a transparent electrode including the above-described graphene-on-substrate with an intermediate layer between a substrate and graphene may be efficiently used as the anode having a high transparency and electrical conductivity.

The HTL may include, for example, polytriphenylamine, but any material that is commonly used to form a HTL may be used without limitation.

The ETL may include, for example, polyoxadiazole, but any material that is commonly used to form an ETL may be used without limitation.

In such an embodiment, any fluorescent or phosphorescent materials that are commonly used in the art as an emitting material may be used to form the emission layer without limitation. In some embodiments, an additional emission material selected from the group consisting of a polymer host, a mixture of a high molecular weight host and a low molecular weight host, a low molecular weight host, and a non-radiative polymer matrix may be used. Any polymer host, any low molecular weight host, and any non-radiative polymer matrix that are commonly used to form an emission layer for an organic light emitting device may be used. In an embodiment, the polymer host may be poly(vinylcarbazole), polyfluorene, poly(p-phenylene vinylene) and polythiophene, for example, but not being limited thereto. In an embodiment, the low molecular weight host are 4,4′-N,N′-dicarbazol-biphenyl (“CBP”), 4,4′-bis[9-(3,6-biphenylcarbozolyl)]-1-1,1′-biphenyl{4,4′-bis[9-(3,6-biphenylcarbazolyl)]-1-1,1′-biphenyl}, 9,10-bis[(2′,7′-t-butyl)-9′,9″-(spirobifluorenyl)anthracene and tetrafluorene, for example, but not being limited thereto. In an embodiment, the non-radiative polymer matrix includes polymethylmethacrylate and polystyrene, for example, but not being limited thereto. In an embodiment, the emission layer may be prepared by vacuum deposition, sputtering, printing, coating or an inkjet process, for example.

The disclosed embodiments will be described in further detail with reference to the following examples. The following examples are for illustrative purposes only and are not intended to limit the scope of the invention.

### PREPARATION EXAMPLE 1

A Cu foil (about 75 μm, available from Wacopa Co. Ltd.) was put in a chamber, and was then thermally treated at about 1,000° C. for about 30 minutes with a supply of H₂ at about 4 standard cubic centimeters per minute (sccm). After flowing CH₄ and H₂ into the chamber at about 20 sccm and about 4 sccm, respectively, for about 30 minutes, the interior of the chamber was naturally cooled, thereby forming a monolayer of graphene of about 2 cm by about 2 cm in size.

Afterward, Cu foil with the graphene sheet was coated with a 5 weight percent (wt %) solution of polymethylmethacrylate (“PMMA”) dissolved in chlorobenzene at about 1,000 revolutions per minute (rpm) for about 60 seconds, and was then immersed in an etchant (CE-100, available from Transene Co. Inc.) for about 1 hour to remove the Cu foil and obtain a graphene sheet attached on the PMMA, which was then washed several times.

### EXAMPLE 1

First of all, about 0.2 gram (g) of boron nitride powder having an average particle diameter of about 10 μm was mixed with about 50 milliliters (mL) of NMP, and was then subjected to ultrasonication for about 5 minutes to disperse flakes of boron nitride in NMP. The flakes of boron nitride dispersed in NMP were coated on a silicon substrate having a thickness of about 600 μm and a diameter of about 4 inches to form a boron nitride film having a thickness in a range from about 5 nm to about 10 nm.

About 0.2 g of graphene flakes of about 1 μm by about 1 μm in average size were mixed with about 50 mL of NMP, and were then subjected to ultrasonication for about 5 minutes to disperse the graphene flakes in the NMP, thereby preparing a graphene flake solution.

The graphene flake solution was coated on the boron nitride film formed on the silicon substrate by spraying, and was then dried to form a graphene flake film having a thickness of about 5 nm, thereby forming a graphene-on-substrate with the graphene and the boron nitride film sequentially stacked on the silicon substrate.

### EXAMPLE 2

First of all, about 0.2 g of boron nitride powder having an average particle diameter of about 10 μm was mixed with about 50 mL of NMP, and was then subjected to ultrasonication for about 5 minutes to disperse flakes of boron nitride in NMP. The flakes of boron nitride dispersed in NMP were coated on a silicon substrate having a thickness of about 600 μm and a diameter of about 4 inches by spraying and were then dried to form a boron nitride film having a thickness of about 5 nm.

The PMMA with the graphene sheet attached thereto from the Preparation Example 1 was transferred to the boron nitride film formed on the silicon substrate, and the PMMA was selectively removed using acetone, thereby forming a graphene-on-substrate with the graphene and the boron nitride film sequentially stacked on the silicon substrate.

### EXAMPLE 3

About 0.2 g of graphene flakes of about 1 μm by about 1 μm in average size were mixed with about 50 mL of NMP, and were then subjected to ultrasonication for about 5 minutes to disperse the graphene flakes in the NMP, thereby preparing a graphene flake solution. The flakes of graphene dispersed in NMP were coated on a silicon substrate having a thickness of about 600 μm and a diameter of about 4 inches by spraying to form a graphene film having a thickness of about 5 nm.

The PMMA with the graphene sheet attached thereto from the Preparation Example 1 was transferred to the graphene flake film formed on the silicon substrate, and the PMMA was selectively removed using acetone, thereby forming a graphene-on-substrate with the graphene and the graphene flake film sequentially stacked on the silicon substrate.

As described above, according to the above embodiments of the invention, a graphene-on-substrate includes an intermediate layer material having a polarity value between the polarity value of the graphene and the polarity value the substrate such that the graphene-to-substrate adhesion is substantially enhanced. Therefore, graphene is less likely to be separated when a device is manufactured using the graphene-on-substrate such that a larger-sized transparent electrode or transistor may be manufactured with a reduced defect rate.

It should be understood that the embodiments described herein should be considered in a descriptive sense only and not for purposes of limitation. Descriptions of features or aspects within each embodiment should typically be considered as available for other similar features or aspects in other embodiments.

What is claimed is:

1. A graphene-on-substrate comprising:
a substrate;
a first intermediate layer disposed on the substrate; and
graphene disposed on the first intermediate layer,
wherein the first intermediate layer comprises a material having a polarity value between a polarity of the substrate and a polarity of the graphene.

2. The graphene-on-substrate of claim 1, wherein the polarity value of the first intermediate layer is in a range from about 20% to about 80% of an entire polarity range between the polarity of the graphene and the polarity of the substrate.

3. The graphene-on-substrate of claim 1, wherein the first intermediate layer has a contact angle with water in a range from about 25° to about 95°.

4. The graphene-on-substrate of claim 1, wherein the first intermediate layer comprises at least one selected from the group consisting of boron nitride, graphene oxide and a polymer-based material.

5. The graphene-on-substrate of claim 1, wherein the first intermediate layer has a thickness in a range of about 0.6 nanometer to about 10 nanometers.

6. The graphene-on-substrate of claim 1, wherein the first intermediate layer has one of a single-layer structure and a multi-layer structure.

7. The graphene-on-substrate of claim 1, wherein the first intermediate layer is a film comprising a plurality of flakes.

8. The graphene-on-substrate of claim 1, wherein the substrate is at least one selected from the group consisting of a metal oxide-based substrate, a silica-based substrate and a plastic substrate.

9. The graphene-on-substrate of claim 1, wherein the substrate comprises at least one selected from the group consisting of SiO₂, ZrO₂, TiO₂, Al₂O₃, glass, quartz, HfO₂, MgO and BeO.

10. The graphene-on-substrate of claim 1, wherein the graphene has a thickness corresponding to a thickness of 2 to 30 layers of single-layer graphene.

11. The graphene-on-substrate of claim 1, further comprising a second intermediate layer disposed on the graphene.

12. The graphene-on-substrate of claim 11, wherein the second intermediate layer has a contact angle with water in a range from about 25° to about 95°.

13. The graphene-on-substrate of claim 11, wherein the second intermediate layer comprises at least one selected from the group consisting of boron nitride, graphene oxide and a polymer-based material.

14. The graphene-on-substrate of claim 11, wherein the second intermediate layer has one of a single-layer structure and a multi-layer structure.

15. The graphene-on-substrate of claim 11, wherein the second intermediate layer is a film comprising a plurality of flakes.

16. The graphene-on-substrate of claim 11, wherein the first intermediate layer is disposed between the substrate and the graphene.

17. The graphene-on-substrate of claim 11, wherein the graphene is disposed between the first and second intermediate layers.

18. A transparent electrode comprising the graphene-on-substrate of claim 1, wherein the substrate of the graphene-on-substrate is at least one of a silica-based substrate and a plastic substrate.

19. A transistor comprising a source electrode, a drain electrode, a gate electrode and a channel, which are defined in a substrate, wherein the channel comprises the graphene-on-substrate of claim 1.

20. A dye-sensitized solar cell comprising:
a semiconductor electrode comprising a graphene-on-substrate and a light absorbing layer;
an electrolyte layer; and
an opposing electrode,
wherein the graphene-on-substrate comprises:
a substrate;
a first intermediate layer disposed on the substrate; and
graphene disposed on the first intermediate layer,
wherein the first intermediate layer comprises a material having a polarity value between a polarity of the substrate and a polarity of the graphene.
